(19) United States
(12) Patent Application Publication
(10) Pub. No.: US 2014/0117477 A1
(43) Pub. Date: May 1, 2014

(54) MAGNETIC MEMORY DEVICES AND METHODS OF FABRICATING THE SAME

(71) Applicants: Jongchul PARK, Seongnam-si (KR); Sechung OH, Suwon-si (KR); Byoungjae BAE, Hwaseong-si (KR); Daeeun JEONG, Yongin-si (KR)

(72) Inventors: Jongchul PARK, Seongnam-si (KR); Sechung OH, Suwon-si (KR); Byoungjae BAE, Hwaseong-si (KR); Daeeun JEONG, Yongin-si (KR)

(21) Appl. No.: 14/067,108

(22) Filed: Oct. 30, 2013

(30) Foreign Application Priority Data
Oct. 31, 2012 (KR) 10-2012-0122385

(51) Int. Cl. H01L 43/02

(52) U.S. Cl. CPC H01L 43/02
USPC 257/421

(57) ABSTRACT

Magnetic memory devices, and methods of fabricating the same, include lower magnetic patterns arranged along first and second directions orthogonal to each other on a substrate, an upper magnetic layer covering at least two of the lower magnetic patterns arranged along the first direction and at least two of the lower magnetic patterns arranged along the second direction, and a tunnel barrier layer the lower magnetic patterns and the upper magnetic layer.

### CROSS-REFERENCE TO RELATED APPLICATIONS

This U.S. non-provisional patent application claims priority under 35 U.S.C. §119 to Korean Patent Application No. 10-2012-0122385, filed on Oct. 31, 2012, in the Korean Intellectual Property Office, the entire contents of which are herein incorporated by reference.

### BACKGROUND

1. Field

Example embodiments of the inventive concepts relate magnetic memory devices and methods of fabricating the same.

2. Description of Related Art

Due to their small size, multifunctionality, and/or low-cost characteristics, semiconductor devices are considered important elements in the electronics industry. Some semiconductor devices include a memory device for storing data, a logic device for processing data, and a system-on-chip configured to perform functions of memory storage and data processing.

As the electronics industry advances, an integration density of the semiconductor device is being increased. However, this results in technical difficulties, such as a decrease of process margin or increasing difficulties in unit processes.

### SUMMARY

Example embodiments of the inventive concepts provide magnetic memory devices with improved magnetic tunnel junction characteristics.

Other example embodiments of the inventive concepts provide methods of fabricating a magnetic memory device with improved magnetic tunnel junction characteristics.

According to example embodiments of the inventive concepts, a magnetic memory device may include a plurality of lower magnetic patterns arranged on a substrate along first and second directions, the first and second directions being orthogonal to each other, an upper magnetic layer covering at least two of the lower magnetic patterns arranged along the first direction and at least two of the plurality of lower magnetic patterns arranged along the second direction, and a tunnel barrier layer between the plurality of lower magnetic patterns and the upper magnetic layer.

In example embodiments, the upper magnetic layer has a magnetization direction fixed perpendicular or parallel to a top surface of the substrate, and the plurality of lower magnetic patterns each have a magnetization direction changeable to be parallel or anti-parallel to the magnetization direction of the upper magnetic layer.

In example embodiments, the plurality of lower magnetic patterns may have thicknesses that are smaller than that of the upper magnetic layer.

In example embodiments, the plurality of lower magnetic patterns may be electrically separated from each other by an insulating gap-filling layer filling spaces between the plurality of magnetic patterns.

In example embodiments, the tunnel barrier layer extends from top surfaces of the plurality of lower magnetic patterns to a top surface of the insulating gap-filling layer.

In example embodiments, the tunnel barrier layer covers top surfaces of the plurality of lower magnetic patterns and may be coplanar with a top surface of the insulating gap-filling layer.

In example embodiments, the device may further include a protection metal pattern between the tunnel barrier layer and the upper magnetic layer. The upper magnetic layer may be in direct contact with a top surface of the protection metal pattern and the top surface of the insulating gap-filling layer.

In example embodiments, an upper width of each of the plurality of lower magnetic patterns may be smaller than a lower width thereof.

In example embodiments, the device may further include an interlayered insulating layer between the substrate and the plurality of lower magnetic patterns, a plurality of lower electrodes protruding from a top surface of the interlayered insulating layer and each respectively connected to one of the plurality of lower magnetic patterns, and an insulating spacer surrounding sidewalls of the plurality of lower electrodes. Each of the plurality of lower magnetic patterns may include a body portion covering a top surface of the lower electrode and an edge portion extending from the body portion to cover a portion of a sidewall of the insulating spacer.

In example embodiments, each of the plurality of lower magnetic patterns may include a plurality of magnetic layers, at least one of the plurality of magnetic layers has a ‘U’-shaped vertical cross-section.

According to example embodiments of the inventive concepts, a magnetic memory device may include a semiconductor substrate with an active pattern, a plurality of word lines extending across the active pattern, a plurality of first impurity regions and a plurality of second impurity regions formed in the active pattern and located at opposing sides of one of the plurality word lines, a plurality of bit lines connected to the first impurity regions and extending across the plurality of word lines, a plurality of lower magnetic patterns each respectively connected to the second impurity regions, an upper magnetic layer covering the plurality of lower magnetic patterns, and a tunnel barrier layer between the plurality of lower magnetic patterns and the upper magnetic layer. The plurality of word lines and the plurality of bit lines may be positioned between the semiconductor substrate and the upper magnetic layer, in vertical cross-sectional view.

The upper magnetic layer may have a magnetization direction fixed to be perpendicular or parallel to a top surface of the substrate, and the plurality of lower magnetic patterns may each have a magnetization direction changeable to be parallel or anti-parallel to the magnetization direction of the upper magnetic layer.

The plurality of lower magnetic patterns may be electrically separated from each other by an insulating gap-filling layer filling spaces between the plurality of lower magnetic patterns.

The tunnel barrier layer may extend from top surfaces of the plurality of lower magnetic patterns to a top surface of the insulating gap-filling layer.

The tunnel barrier layer may cover top surfaces of the plurality of lower magnetic patterns and is coplanar with a top surface of the insulating gap-filling layer.

The device may further include a protection metal pattern between the tunnel barrier layer and the upper magnetic layer, wherein the upper magnetic layer is in direct contact with a top surface of the protection metal pattern and the top surface of the insulating gap-filling layer.

The plurality of active patterns may be parallel to an oblique direction with respect to the plurality of word lines and the plurality of bit lines.

According to example embodiments of the inventive concepts, a method of fabricating a magnetic memory device may include forming plurality of lower electrodes penetrating an interlayered insulating layer, on a substrate, depositing a lower magnetic layer on the interlayered insulating layer, patterning the lower magnetic layer to form a plurality of lower magnetic patterns each respectively connected to one the plurality of lower electrodes, forming an insulating gap-filling layer to fill spaces between the plurality of lower magnetic patterns, and depositing an upper magnetic layer on the insulating gap-filling layer to cover the plurality of lower magnetic patterns in common.

The method may further include, before the depositing of the upper magnetic layer, forming a tunnel barrier layer to cover top surfaces of the plurality of lower magnetic patterns and a top surface of the insulating gap-filling layer.

The method may further include, before the forming of the plurality of lower magnetic patterns, depositing a tunnel barrier layer on the lower magnetic layer, wherein the forming of the plurality of lower magnetic patterns comprises patterning the tunnel barrier layer and the lower magnetic layer.

The depositing of the upper magnetic layer may include forming the upper magnetic layer in direct contact with top surfaces of the tunnel barrier layer and the insulating gap-filling layer.

The method may further include, before the forming of the plurality of lower magnetic patterns, successively depositing a tunnel barrier layer and a protection metal layer on the lower magnetic layer, wherein the forming of the plurality of lower magnetic patterns comprises patterning the tunnel barrier layer, the protection metal layer and the lower magnetic layer.

The depositing of the upper magnetic layer may include forming the upper magnetic layer in direct contact with top surfaces of the protection metal layer and the insulating gap-filling layer.

According to other example embodiments, a magnetic memory device includes a plurality of word lines extending, in a first direction, within an active region of substrate, wherein a first impurity region and a second impurity region are respectively formed within the active region of the substrate and on opposing sides of each of the word lines, a plurality of bit lines extending a second direction, wherein the second direction is substantially perpendicular to the first direction, and the plurality of bit lines are electrically connected to and extend over the first impurity region along the second direction, a magnetic tunnel junction including a free layer pattern, at least one insulating layer and at least one reference layer sequentially stacked, wherein the free layer pattern extends along the first direction over the entire active region except for regions corresponding to the word lines and the bit lines, and the free layer pattern extends over the first and second impurity regions along the second direction.

The free layer pattern may extend over the first impurity region along the first direction.

The reference layer may have a fixed magnetization direction, and the free layer pattern may be configured to control an electrical resistance of the magnetic tunnel junction by changing a magnetization direction of the free layer pattern to either a parallel state or an antiparallel state relative to the magnetization direction of the reference layer.

The free layer pattern may consist of a plurality of line patterns each arranged two-dimensionally over the active region of the substrate.

According to other example embodiments, a method of fabricating a magnetic memory device includes providing a plurality of lower electrodes over a substrate, arranging a plurality of lower magnetic patterns two-dimensionally on a substrate, wherein the plurality of lower magnetic patterns are insulated from each other and respectively electrically connected to the plurality of lower electrodes, and sequentially forming at least one tunnel barrier layer and at least one reference layer over the plurality of lower magnetic patterns.

The arranging of the plurality of lower magnetic patterns may include depositing a lower magnetic layer, and etching the lower magnetic layer so as to form the plurality of lower magnetic patterns spaced apart from each other, prior to forming the at least one tunnel barrier layer.

The arranging of the plurality of lower magnetic patterns may include locally forming the plurality of lower magnetic patterns spaced apart from each other without using a patterning process.

The arranging of the plurality of lower magnetic patterns may include forming the plurality of lower magnetic patterns to partially cover sidewalls of the plurality of lower electrodes.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram illustrating a cell array of a magnetic memory device according to example embodiments of the inventive concepts.

FIGS. 2A through 2D are sectional views schematically illustrating a magnetic memory device according to example embodiments of the inventive concepts.

FIG. 3 is a plan view of a magnetic memory device according to example embodiments of the inventive concepts.

FIG. 4 is a sectional view that is taken along lines I-I′ and II-II′ of FIG. 3 to illustrate magnetic memory devices according to example embodiments of the inventive concepts.

FIGS. 5 through 14 are enlarged sectional views of a portion A of FIG. 4, which are presented to describe memory elements of the magnetic memory devices according to example embodiments of the inventive concepts.

FIG. 15 is a sectional view that is taken along lines I-I′ and II-II′ of FIG. 3 to illustrate magnetic memory devices according to other example embodiments of the inventive concepts.

FIGS. 16 through 18 are enlarged sectional views of a portion B of FIG. 15, which are presented to describe memory elements of magnetic memory devices according to other example embodiments of the inventive concepts.

FIG. 19 is a plan view of a magnetic memory device according to other example embodiments of the inventive concepts.

FIG. 20 is a sectional view that is taken along lines I-I′ and II-II′ of FIG. 19 to illustrate magnetic memory devices according to other example embodiments of the inventive concepts.

FIG. 21 is a schematic block diagram illustrating an example of electronic systems including a magnetic memory device according to example embodiments of the inventive concepts.

FIG. 22 is a schematic block diagram illustrating an example of memory cards including the magnetic memory devices according to the embodiments of the inventive concepts.

FIG. 23 is a schematic block diagram illustrating an example of information processing systems including a magnetic memory device according to example embodiments of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Example embodiments relate magnetic memory devices and methods of fabricating the same.

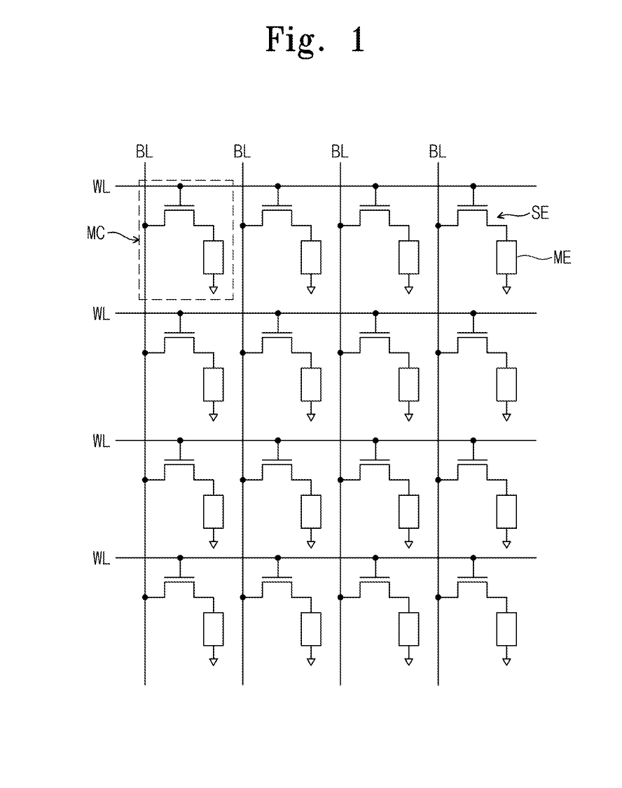

FIG. 1 is a circuit diagram illustrating a cell array of a magnetic memory device according to example embodiments of the inventive concepts.

Referring to FIG. 1, a plurality of unit memory cells MC may be arranged two-dimensionally or three-dimensionally. Each of the unit memory cells MC may be provided between a word line WL and a bit line BL, which are provided to cross each other, to connect them each other. Each of the unit memory cells MC may include a magnetic memory element ME and a selection element SE. The selection elements SE and the magnetic memory elements ME may be electrically connected in series to each other. The magnetic memory element ME may be provided between the bit line BL and the selection element SE to connect them each other, and the selection element SE may be provided between the magnetic memory element ME and the word line WL to connect them each other.

The magnetic memory element ME may include a magnetic tunnel junction MTJ. The selection element SE may be configured to control selectively a flow of electric charges passing through the magnetic tunnel junction. For example, the selection element SE may be one of a diode, a PNP bipolar transistor, a NPN bipolar transistor, a NMOS field effect transistor, and a PMOS field effect transistor.

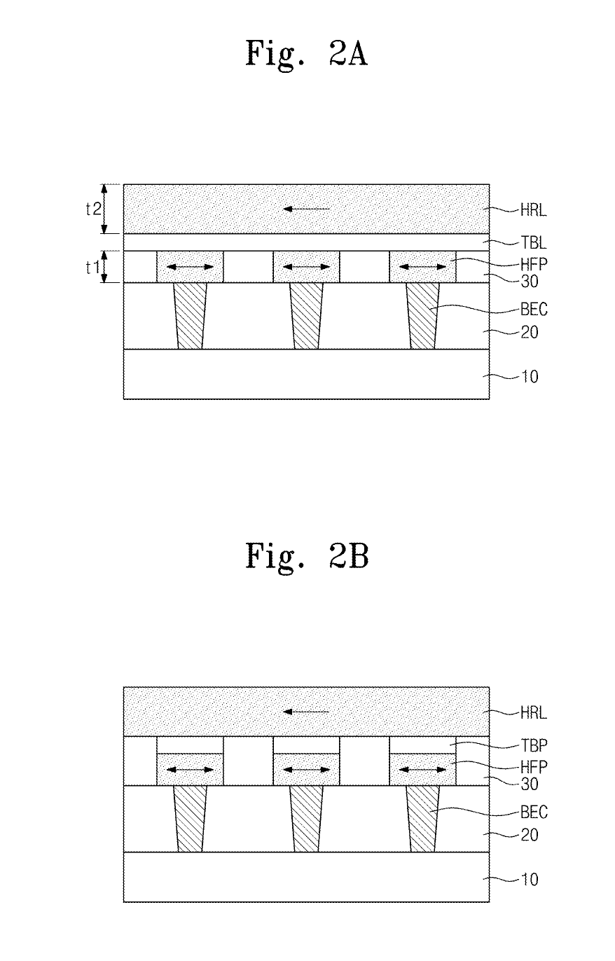

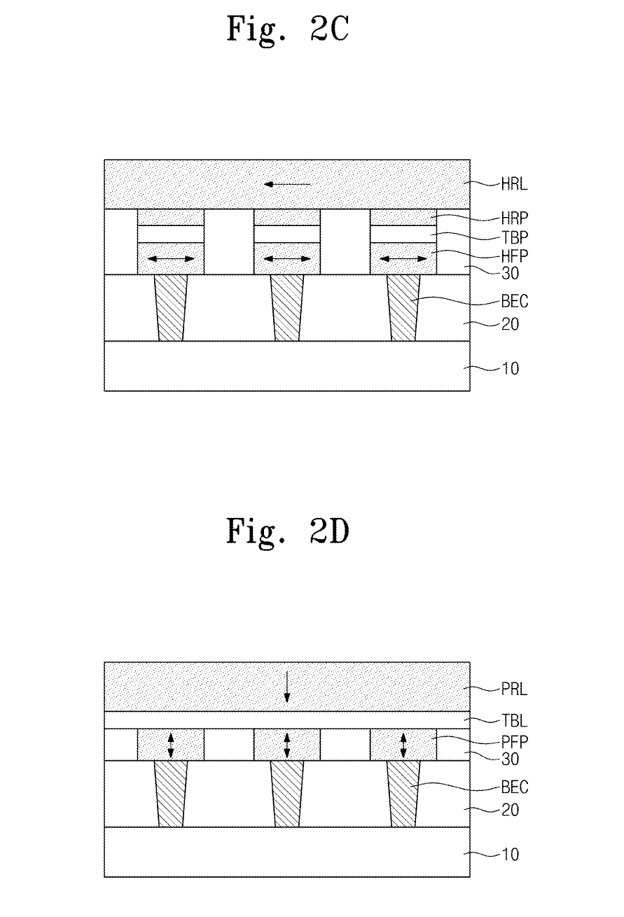

Magnetic memory devices according to example embodiments of the inventive concepts and methods of fabricating the same will be described with reference to FIGS. 2A through 2C. FIGS. 2A through 2D are sectional views schematically illustrating a magnetic memory device according to example embodiments of the inventive concepts.

Referring to FIGS. 2A through 2D, an interlayered insulating layer 20, in which lower electrodes BEC are provided, may be formed on a lower layer 10. The lower layer 10 may include semiconductor devices, wires, and a plurality of stacked insulating layers. The lower electrodes BEC may be electrically connected to the semiconductor devices and/or the wires in the lower layer 10. The lower electrodes BEC may be two-dimensionally separated from each other, in plan view. In example embodiments, the lower electrodes BEC may be regularly arranged spaced apart from each other in orthogonal two directions (e.g., first and second directions). Alternatively, the lower electrodes BEC may be provided to form a zigzag arrangement, in plan view.

Referring to FIGS. 2A through 2D, layers constituting lower magnetic patterns HFP may be deposited on the interlayered insulating layer 20 provided with the lower electrodes BEC. The layers may be formed using one of deposition techniques to cover wholly the top surface of the interlayered insulating layer 20 provided with the lower electrodes BEC.

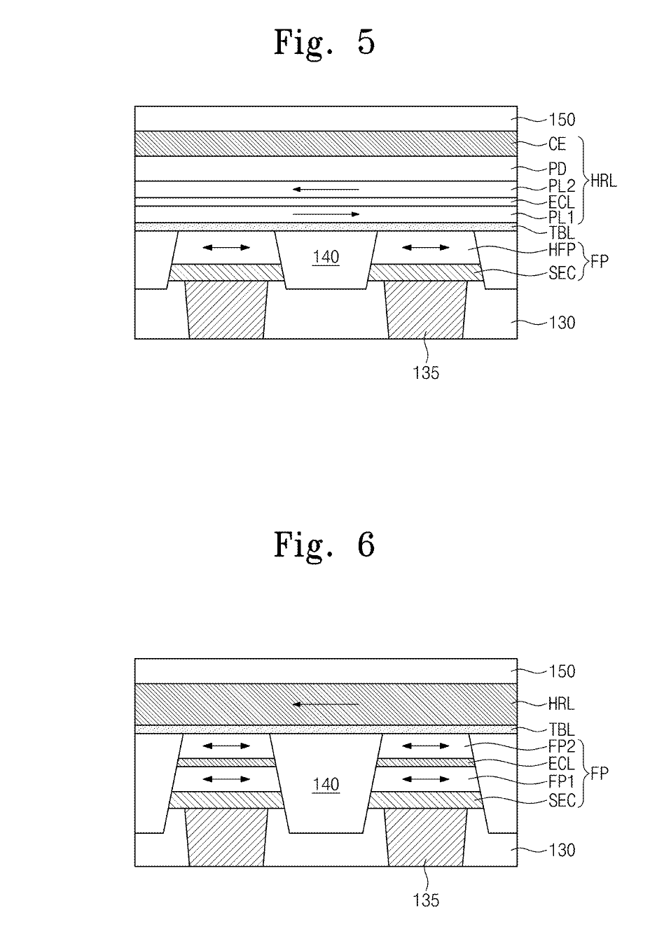

A mask pattern may be formed on the layers and be etched using the mask pattern as an etch mask to expose the interlayered insulating layer 20. For example, a dry etching process or an ion beam etching process may be used to etch the layers. As the result of the etching of the layers, lower magnetic patterns HFP may be formed to be connected to the lower electrodes BEC, respectively. Structural features of the lower magnetic patterns HFP will be described in more detail with reference to FIGS. 5 through 9.

Thereafter, an insulating gap-filling layer 30 may be formed to fill a gap between the lower magnetic patterns HFP. The formation of the insulating gap-filling layer 30 may include depositing an insulating layer to fill a gap between the lower electrodes BEC and the lower magnetic patterns HFP, and then, planarizing the deposited insulating layer to expose top surfaces of the lower magnetic patterns HFP. Here, the deposition of the insulating layer may be performed using a deposition technique having a good step coverage property, such as a physical vapor deposition PVD), a chemical vapor deposition (CVD), or an atomic layer deposition (ALD). The planarization process may be performed using a chemical mechanical polishing (CMP) process or a dry etch-back process. In example embodiments, as the result of the planarization process, the insulating gap-filling layer 30 may have a top surface that is coplanar with those of the lower magnetic patterns HFP. Further, the insulating gap-filling layer 30 may be in direct contact with sidewalls of the lower magnetic patterns HFP.

According to the example embodiment shown in FIGS. 2A and 2D, a tunnel barrier layer TBL may be formed to be in contact with top surfaces of the lower magnetic patterns HFP and the insulating gap-filling layer 30, after the formation of the lower magnetic patterns HFP and the insulating gap-filling layer 30. In addition, an upper magnetic layer HRL and PRL may be formed on the tunnel barrier layer TBL.

According to the example embodiment shown in FIG. 2B, the tunnel barrier layer may be deposited directly after the deposition of the layers constituting the lower magnetic patterns HFP. Thereafter, a mask pattern (not shown) may be formed on the tunnel barrier layer, the tunnel barrier layer and the layers may be etched using the mask pattern as an etch mask to expose the interlayered insulating layer 20. Accordingly, the lower magnetic patterns HFP may be formed to be connected to the lower electrodes BEC, respectively, and tunnel barrier patterns TBP may be formed to cover a top surface of each of the lower magnetic patterns HFP. In addition, the insulating gap-filling layer 30 may be formed to fill a gap between the lower magnetic patterns HFP and the tunnel barrier patterns TBP. In example embodiments, the tunnel barrier patterns TBP may have top surfaces that are coplanar with those of the insulating gap-filling layer 30. Next, the upper magnetic layer HRL may be deposited on top surfaces of the tunnel barrier patterns TBP and the insulating gap-filling layer 30.

According to the embodiment shown in FIG. 2C, the tunnel barrier layer and a protection metal layer may be deposited directly after the deposition of the layers constituting the lower magnetic patterns HFP. Thereafter, a mask pattern may be formed on the protection metal layer, the protection metal layer, the tunnel barrier layer, and the layers may be etched using the mask pattern as an etch mask to expose the interlayered insulating layer 20. Accordingly, the lower magnetic patterns HFP may be formed to be connected to the lower electrodes BEC, respectively, and the tunnel barrier patterns TBP may be formed to cover a top surface of each of the lower magnetic patterns HFP, and a protection metal pattern HRP may be formed to cover a top surface of the tunnel barrier pattern TBP. In addition, the insulating gap-filling layer 30 may be formed to fill a gap between the lower magnetic patterns HFP, the tunnel barrier patterns TBP, and the protection metal patterns HRP. The tunnel barrier patterns TBP may have top surfaces that are coplanar with that of the insulating gap-filling layer 30. Next, the upper magnetic layer HRL may be deposited on the top surfaces of the protection metal patterns HRP and the insulating gap-filling layer 30. The protection metal patterns HRP may include a metal material, a metal oxide, or a magnetic material.

In these magnetic memory devices, the lower magnetic pattern HFP, the upper magnetic layer HRL, and the tunnel barrier layer TBL therebetween may constitute the magnetic tunnel junction MTJ. Here, the upper magnetic layer HRL may have a fixed magnetization direction, regardless of the presence of an external magnetic field under typical user condition, and thus, it may serve as a reference layer of the magnetic tunnel junction MTJ. The lower magnetic patterns HFP may be a free layer whose magnetization direction can be easily changed by an external magnetic field.

Furthermore, according to the example embodiments shown in FIGS. 2A through 2C, the upper magnetic layer HRL may have a magnetization direction that is fixed parallel to the top surface of the lower layer 10, while the lower magnetic patterns HFP may have a magnetization direction that is parallel to the top surface of the lower layer 10 but is constrained to be parallel or anti-parallel to a magnetization direction of the upper magnetic layer HRL. By contrast, according to the example embodiment shown in FIG. 2D, an upper magnetic layer PRL may have a magnetization direction that is fixed to be substantially perpendicular to the top surface of the lower layer 10, while the lower magnetic patterns PFP may have a magnetization direction that is substantially perpendicular to the top surface of the lower layer 10 but is constrained to be parallel or anti-parallel to a magnetization direction of the upper magnetic layer PRL.

The magnetic tunnel junction MTJ may have an electric resistance that is much greater when the reference layer and the free layer have magnetization directions antiparallel to each other than when they have magnetization directions parallel to each other. This means that the electric resistance of the magnetic tunnel junction MTJ can be controlled by changing the magnetization direction of the free layer. Accordingly, this change in electric resistance may be used as data storing mechanism of the magnetic memory element ME or the memory cell MC. For example, in order to store data into each magnetic memory element ME independently, the free layers of the memory cells MC may be electrically and spatially separated from each other. In example embodiments, the reference layer may be shared by a plurality of the magnetic memory elements ME.

The formation of the magnetic tunnel junction may include sequentially depositing the free layer, the tunnel barrier layer, and the reference layer and performing a patterning process to form patterns separated from each other. In this case, an etch-target layer may have an increased thickness, and thus, there may be technical difficulties in finishing quickly the etching process or in separating completely patterns from each other. In addition, an amount of etch by-products, which may occur during etching the magnetic layers, may be increased, and the etch by-products may be re-deposited on sidewalls of the patterns to make electrical short circuits between the patterns.

By contrast, according to the present example embodiments, as described with reference to FIGS. 2A through 2D, the etching process may be performed to the layers constituting the lower magnetic patterns HFP, before the deposition of the upper magnetic layer HRL wholly covering the lower magnetic patterns HFP. Accordingly, it is possible to reduce a thickness of an etch-target layer, to improve a margin of the etching process, and to reduce an amount of the etch by-products.

Further, according to example embodiments of the inventive concepts, the lower magnetic patterns HFP serving as the free layer may have a thickness t1 that is smaller than a thickness t2 of the upper magnetic layer HRL serving as the reference layer. Accordingly, it is possible to relieve an etching burden and reduce the amount of the etch by-products, in the etching process for forming the lower magnetic patterns HFP. In other example embodiments, the lower magnetic patterns HFP may have a thickness that is substantially equivalent to or greater than that of the upper magnetic layer HTL.

Furthermore, because the upper magnetic layer HRL is formed to cover wholly the lower magnetic patterns HFP with a uniform thickness, a magnetic field from the upper magnetic layer HRL can be uniformly applied to the lower magnetic pattern HFP. This makes it possible to improve electric characteristics of the magnetic tunnel junction. In example embodiments, the upper magnetic layer HRL, which is the uppermost layer of the magnetic layers, may be provided to have a plate structure, thereby serving as a magnetic shielding layer.

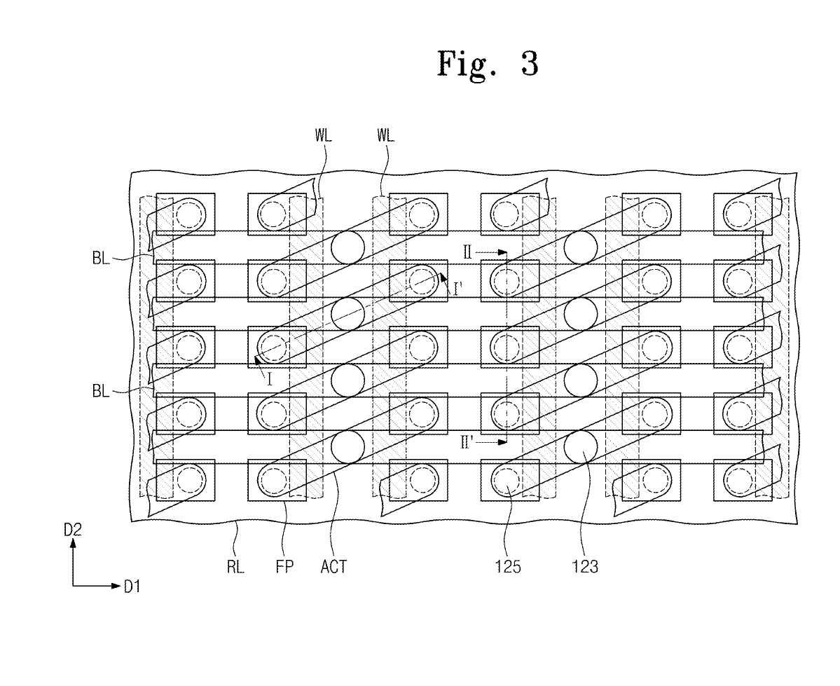

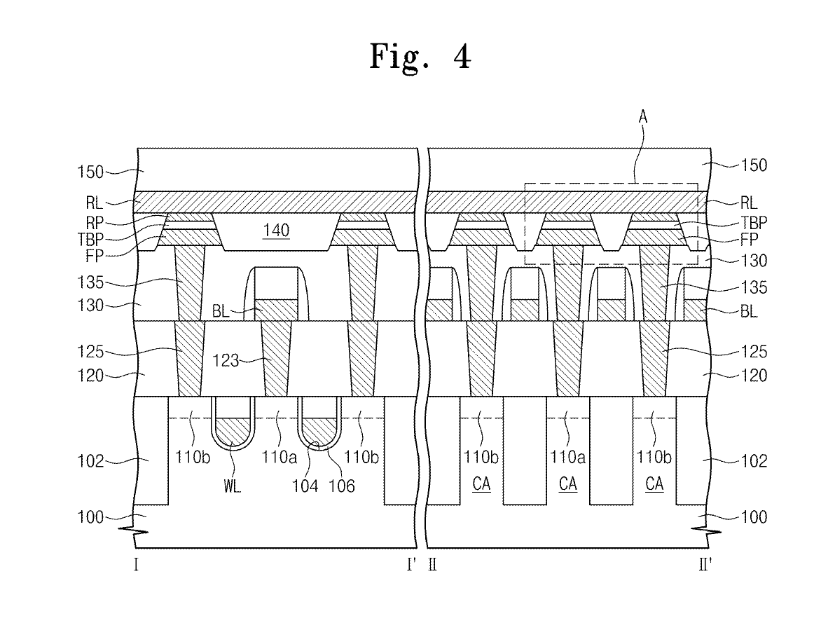

FIG. 3 is a plan view of a magnetic memory device according to example embodiments of the inventive concepts. FIG. 4 is a sectional view that is taken along lines I-I′ and II′ of FIG. 3 to illustrate magnetic memory devices according to example embodiments of the inventive concepts.

Referring to FIGS. 3 and 4, device isolation patterns 102 may be formed on a semiconductor substrate 100 to define active patterns ACT. The semiconductor substrate 100 may be a silicon wafer, a germanium wafer, and/or a silicon-germanium wafer.

The active patterns ACT may be two-dimensionally arranged along a plurality of rows and a plurality of columns, and each of the active patterns ACT may have a rectangular or bar shape elongated to cross both of first and second directions that are perpendicular to each other or along an oblique direction. In example embodiments, each of rows of the active patterns ACT may be arranged along the first direction, and each of columns of the active patterns ACT may be arranged along the second direction. The active patterns ACT may be doped with dopants of a first conductivity type.

At least one gate recess region 104 may be provided to cross each column of the active patterns ACT. The gate recess region 104 may have a groove-shaped structure extending along the second direction. The gate recess region 104 may have a depth that is smaller than a depth of the device isolation pattern 102. In example embodiments, a pair of the gate recess regions 104 may be provided to cross each column of the active patterns ACT. In this case, a pair of cell transistors may be formed in each active pattern.

A word line WL may be provided in each gate recess region 104, and a gate dielectric 106 may be provided between the word line WL and the gate recess region 104. The word line WL may have a line shaped structure extending along the second direction and crossing an active line pattern ALP. A region recessed by the gate recess region 104 may serve as a channel region for the cell transistor including the word line WL.

Gate hardmask patterns may be provided on the word lines WL, respectively. The gate hardmask patterns may have top surfaces that are substantially coplanar with the top surface of the semiconductor substrate 100.

For example, the word line WL may include at least one of doped semiconductor materials (e.g., doped silicon), metals (e.g., tungsten, aluminum, titanium, and/or tantalum), conductive metal nitrides (e.g., titanium nitride, tantalum nitride, and/or tungsten nitride), or metal-semiconductor compounds (e.g., metal silicide).

The gate dielectric 106 may include at least one of oxide (e.g., silicon oxide), nitride (e.g., silicon nitride), oxynitride (e.g., silicon oxynitride), and/or high-k dielectrics (e.g., insulating metal oxides such as hafnium oxide or aluminum oxide). The gate hardmask pattern may include at least one of oxide (e.g., silicon oxide), nitride (e.g., silicon nitride), and/or oxynitride (e.g., silicon oxynitride).

A first impurity region 110a may be formed in each active pattern ACT at a side of the word line WL, and a second impurity region 110b may be formed in each active pattern ACT at other side of the word line WL. In example embodiments, the first impurity region 110a may be provided in each active pattern ACT between a pair of the word lines WL, and a pair of the second impurity regions 110b may be provided in two portions of each active pattern ACT separated by the pair of the word lines WL. In other words, in each active pattern ACT, a pair of cell transistors may share the first impurity region 110a. First and second impurity regions 110a and 110b may serve as source/drain regions of the cell transistors. The first and second impurity regions 110a and 110b may be doped to have a second conductivity type that is different from the first conductivity type of the active pattern ACT. One of the first and second conductivity types may be n-type, and the other p-type.

Referring to FIGS. 3 and 4, a first interlayered insulating layer 120 may be provided on the whole top surface of the semiconductor substrate 100. The first interlayered insulating layer 120 may be formed of oxide (e.g., silicon oxide). First and second contact plugs 123 and 125 may be formed through the first interlayered insulating layer 120. First contact plugs 123 may be electrically coupled to the first impurity regions 110a, respectively. Second contact plugs 125 may be electrically coupled to the second impurity regions 110b, respectively.

The first and second contact plugs 123 and 125 may include at least one of doped semiconductor materials (e.g., doped silicon), metals (e.g., tungsten, aluminum, titanium, and/or tantalum), conductive metal nitrides (e.g., titanium nitride, tantalum nitride, and/or tungsten nitride), or metal-semiconductor compounds (e.g., metal silicide).

Bit lines BL may be provided on the first interlayered insulating layer 120 to extend along the first direction. The bit lines BL may be provided to cross the word lines WL. The bit lines BL may be electrically coupled to the first contact plugs 123 arranged along the first direction.

A second interlayered insulating layer 130 may be provided on the first interlayered insulating layer 120 to cover the second contact plugs 125 and the bit lines BL. Hardmask patterns may be provided on the bit lines BL.

Lower electrodes 135 may be provided through the second interlayered insulating layer 130, and each of the lower electrodes 135 may be electrically coupled to the second contact plug 125. In example embodiments, in plan view, the lower electrodes 135 may be arranged spaced apart from each other in the first and second directions. The lower electrodes 135 may be provided to have a zigzag arrangement, in plan view.

Magnetic memory elements (ME of FIG. 1) may be provided on the lower electrodes 135, respectively. According to example embodiments of the inventive concepts, the lower magnetic patterns FP may be coupled to the lower electrodes 135, respectively. An insulating gap-filling layer 140 may be provided to fill spaces between the lower magnetic patterns FP, and an upper magnetic layer RL may be formed on top surfaces of the lower magnetic patterns FP and a top surface of the insulating gap-filling layer 140. The upper magnetic layer RL may be provided to cover wholly the lower magnetic patterns FP that are two-dimensionally arranged on the semiconductor substrate 100. For example, the upper magnetic layer RL may have a plate shaped structure, and a top surface thereof may be in contact with a capping insulating layer 150. Further, a tunnel barrier layer TBP may be interposed between the lower magnetic patterns FP and the upper magnetic layer RL. In example embodiments, in the case where the lower magnetic patterns FP and the upper magnetic layer RL are used for a free layer and a reference layer, respectively, a thickness of the lower magnetic patterns FP may be smaller than that of the upper magnetic layer RL.

Here, the lower magnetic patterns FP may be formed by a patterning process, as described with reference to FIGS. 2A through 2D. For example, an etching process may be performed to layers constituting the lower magnetic patterns FP, and the top surface of the second interlayered insulating layer 130 exposed between the lower magnetic patterns FP may be recessed during this etching process.

The structural features of the magnetic memory element according to example embodiments of the inventive concepts will be described in detail with reference to FIGS. 5 through 14.

FIGS. 5 through 14 are enlarged sectional views of a portion A of FIG. 4, which are presented to describe memory elements of the magnetic memory devices according to example embodiments of the inventive concepts.

Referring to FIGS. 5 through 10, the tunnel barrier layer TBL and the upper magnetic layers HRL and PRL may cover a plurality of the lower magnetic patterns FP that are arranged along the first and second directions. In example embodiments, the tunnel barrier layer TBL and the upper magnetic layers HRL and PRL may be formed to have a plate structure covering wholly the lower magnetic patterns FP. The insulating gap-filling layer 140 may be provided to fill spaces between the lower magnetic patterns FP. In the present example embodiment, top surfaces of the lower magnetic patterns FP and the insulating gap-filling layer 140 may be in direct contact with the tunnel barrier layer TBL.

In the example embodiments shown in FIGS. 5 through 14, the tunnel barrier layer TBL or the tunnel barrier pattern TBP may be formed to have a thickness that is smaller than a spin diffusion distance of electrons passing therethrough. The tunnel barrier layer TBL or the tunnel barrier pattern TBP may include an insulating material. For example, the tunnel barrier layer TBL or the tunnel barrier pattern TBP may include at least one of magnesium oxide, titanium oxide, aluminum oxide, magnesium-zinc oxide, or magnesium-boron oxide.

The lower magnetic patterns FP shown in FIGS. 5 through 10 may be formed by a patterning process, as described with reference to FIGS. 2A through 2D. In this case, the lower magnetic pattern FP may be formed to have an upper width that is smaller than its lower width. Further, each of the lower magnetic patterns FP may have a trapezoidal vertical section, whose upper width is smaller than its lower width.

In the example embodiments shown in FIGS. 5 through 10, because, before the formation of the tunnel barrier layer TBL, the etching process is performed to the layers constituting the lower magnetic patterns FP, it is possible to prevent the tunnel barrier layer TBL from being degraded by etch by-products, which may occur in the etching process.

Referring to FIG. 5, each of the lower magnetic patterns FP may include a horizontal free pattern HFP and a seed electrode pattern SEC provided between the horizontal free pattern HFP and the lower electrode 135.

The horizontal free pattern HFP may be substantially parallel to the top surface of the substrate and have a switchable magnetization direction. A top surface of the horizontal free pattern HFP may be in direct contact with a bottom surface of the tunnel barrier layer TBL.

The seed electrode pattern SEC may be coupled to a top surface of the second contact plug 125. The seed electrode pattern SEC may include a conductive material having low reactivity. For example, the seed electrode pattern SEC may include a conductive metal nitride. In example embodiments, the seed electrode pattern SEC may include at least one of titanium nitride, tantalum nitride, tungsten nitride, or titanium aluminum nitride.

Referring to FIG. 5, the upper magnetic layer HRL may include a first pinning pattern PL1, an exchange coupling pattern ECL, a second pinning pattern PL2, a pinned pattern PD, and a capping electrode pattern CE stacked in a sequential manner.

The first pinning pattern PL1 may be in direct contact with the tunnel barrier layer TBL, and the second pinning pattern PL2 may be in direct contact with the pinned pattern PD.

Due to the presence of the pinned pattern PD, the second pinning pattern PL2 may have a magnetization direction fixed to a specific direction. Due to the presence of the exchange coupling pattern ECL, the first pinning pattern PL1 may have a fixed magnetization direction that is antiparallel to that of the second pinning pattern PL2.

The first pinning pattern PL1 may include a ferromagnetic material. For example, the first pinning pattern PL1 may include at least one of cobalt-iron-boron (CoFeB), cobalt-iron (CoFe), nickel-iron (NiFe), cobalt-iron-platinum (CoFePt), cobalt-iron-palladium (CoFePd), cobalt-iron-chromium (CoFeCr), cobalt-iron-terbium (CoFeTb), cobalt-iron-gadolinium (CoFeGd), or cobalt-iron-nickel (CoFeNi). For realizing an in-plane magnetization, a content ratio of terbium (Tb) in cobalt-iron-terbium (CoFeTb) may be smaller than about 10%. Similarly, for realizing the in-plane magnetization, a content ratio of gadolinium (Gd) in cobalt-iron-gadolinium (CoFeGd) may be smaller than about 10%.

The exchange coupling pattern ECL may include a rare metal. For example, the exchange coupling pattern ECL may include at least one of ruthenium (Ru), iridium (Ir), or rhodium (Rh).

The pinned pattern PD may include an antiferromagnetic material. For example, the pinned pattern PD may include at least one of platinum manganese (PtMn), iridium manganese (IrMn), manganese oxide (MnO), manganese sulfide (MnS), manganese telluride (MnTe), or manganese fluoride (MnF).

The capping electrode pattern CE may be formed of a conductive material. For example, the capping electrode pattern CE may include a metal. In example embodiments, the capping electrode pattern CE may include at least one of ruthenium (Ru), tantalum (Ta), palladium (Pd), titanium (Ti), platinum (Pt), silver (Ag), gold (Au), or copper (Cu).

Referring to FIG. 6, each of the lower magnetic patterns FP may include the seed electrode pattern SEC, a first free pattern FP1, a free exchange coupling pattern ECL and a second free pattern FP2 stacked in a sequential manner.

The first free pattern FP1 may be in direct contact with the seed electrode pattern SEC, and the second free pattern FP2 may be in direct contact with the tunnel barrier layer TBL. For example, a bottom surface of the first free pattern FP1 may be in contact with the seed electrode pattern SEC, and a top surface of the first free pattern FP1 may be in contact with the free exchange coupling pattern ECL. A top surface of the second free pattern FP2 may be in contact with the tunnel barrier layer TBL, and a bottom surface of the second free pattern FP2 may be in contact with the free exchange coupling pattern ECL. In other words, the free exchange coupling pattern ECL may be interposed between the first free pattern FP1 and the second free pattern FP2.

The first and second free patterns FP1 and FP2 may have magnetization directions that are parallel to the top surface of the semiconductor substrate 100 and are switchable. The second free pattern FP2 and the first free pattern FP1 may be magnetically coupled with each other to have magnetization directions antiparallel to each other. This may result from a magneto-static field or a stray field by the first and second free patterns FP1 and FP2. The second free pattern FP2 may be formed of the same magnetic material as the first free pattern FP1. The free exchange coupling pattern ECL may be formed of a non-magnetic metal oxide.

In the case where the first and second free patterns FP1 and FP2 contain iron and/or cobalt, the first and second free patterns FP1 and FP2 may include at least one of cobalt-iron-boron (CoFeB), cobalt-iron (CoFe), cobalt-iron-platinum (CoFePt), cobalt-iron-palladium (CoFePd), cobalt-iron-chromium (CoFeCr), cobalt-iron-terbium (CoFeTb), cobalt-iron-gadolinium (CoFeGd), or cobalt-iron-nickel (CoFeNi). For realizing an in-plane magnetization, a content ratio of terbium (Tb) in cobalt-iron-terbium (CoFeTb) may be less than about 10%. Similarly, for realizing the in-plane magnetization, a content ratio of gadolinium (Gd) in cobalt-iron-gadolinium (CoFeGd) may be less than about 10%.

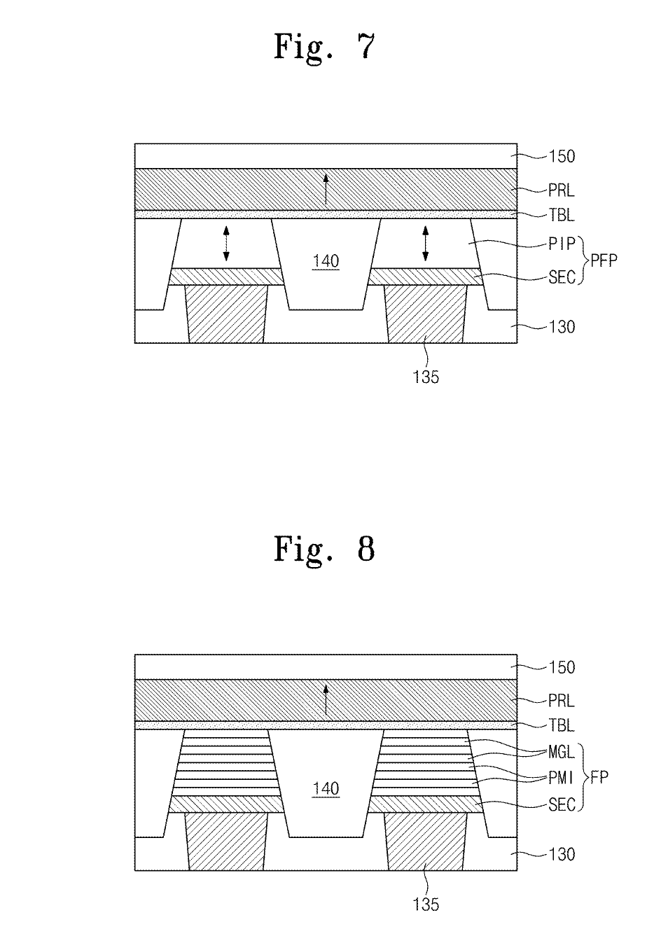

Referring to FIG. 7, each of the lower magnetic patterns PFP may include the seed electrode pattern SEC and a perpendicular free pattern PIP.

The seed electrode pattern SEC may be couple to the top surface of the second contact plug 125 and include a conductive metal nitride.

The perpendicular free pattern PIP may be in direct contact with the bottom surface of the tunnel barrier layer TBL. The perpendicular free pattern PIP may be configured to have a magnetization direction that is perpendicular to the top surface of the substrate and is switchable. The magnetization direction of the perpendicular free pattern PIP may be switched to be parallel or antiparallel to that of the upper magnetic layer PRL serving as the reference layer.

The perpendicular free pattern PIP may be formed of a magnetic material having a perpendicular magnetic anisotropy. The perpendicular free pattern PIP may include at least one of, for example, perpendicular magnetic materials (e.g., CoFeTb, CoFeGd, CoFeDy, and so forth), perpendicular magnetic materials having L10 structure, CoPt with the hexagonal close packing (HCP) structure, or alloys containing at least one thereof.

Referring to FIG. 8, the lower magnetic pattern FP may include at least one magnetic pattern MGL and at least one perpendicular magnetization inducing pattern PMI, which may be alternatingly stacked on the seed electrode pattern SEC, in addition to the seed electrode pattern SEC.

The magnetic patterns MGL may be formed of a ferromagnetic material, and the perpendicular magnetization inducing pattern PMI may be formed of a metal oxide.

For example, the magnetic patterns MGL may include at least one of cobalt-iron-boron (CoFeB), cobalt-iron (CoFe), nickel-iron (NiFe), cobalt-iron-platinum (CoFePt), cobalt-iron-palladium (CoFePd), cobalt-iron-chromium (CoFeCr), cobalt-iron-terbium (CoFeTb), cobalt-iron-gadolinium (CoFeGd), or cobalt-iron-nickel (CoFeNi).

The perpendicular magnetization inducing pattern PMI may be formed to be in direct contact with the magnetic pattern MGL, and as the result of this direct contact, a magnetization direction of the magnetic layer can be changed to be parallel to a thickness direction (i.e., a normal direction) of the magnetic pattern MGL, although the magnetic pattern MGL exhibits an intrinsically in-plane magnetization property. In other words, the perpendicular magnetization inducing layer may serve as an external factor changing a magnetization direction of the magnetic pattern MGL to be parallel to the normal direction of the magnetic pattern MGL.

For example, the perpendicular magnetization inducing pattern PMI may include at least one of magnesium oxide, tantalum oxide, titanium oxide, aluminum oxide, magnesium zinc oxide, hafnium oxide, or magnesium boron oxide. The perpendicular magnetization inducing pattern PMI may have an electric resistivity greater than that of the magnetic patterns MGL. The perpendicular magnetization inducing pattern PMI may be thinner than the magnetic patterns MGL.

The uppermost one of the perpendicular magnetization inducing patterns PMI may be in direct contact with the tunnel barrier layer TBL. Alternatively, a perpendicular magnetization preserving pattern (not shown) may be interposed between the tunnel barrier layer TBL and the uppermost one of the perpendicular magnetization inducing patterns PMI. The perpendicular magnetization preserving pattern may be formed of a material having smaller resistivity than the perpendicular magnetization inducing pattern PMI. For example, the perpendicular magnetization preserving pattern may be formed of at least one of noble metals (e.g., ruthenium, rhodium, palladium, silver, osmium, iridium, platinum, or gold) or copper.

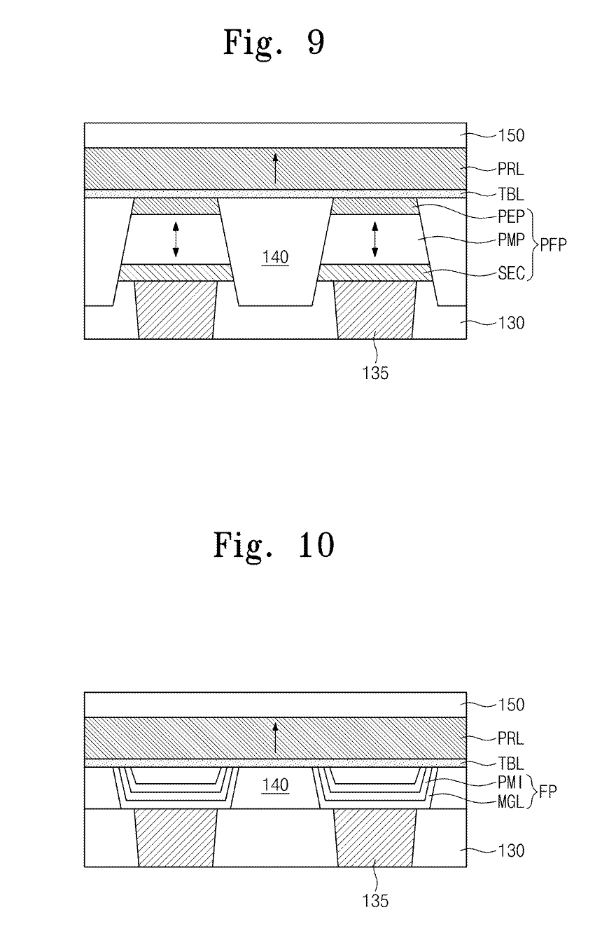

Referring to FIG. 9, each of the lower magnetic patterns PFP may include the seed electrode pattern SEC, the perpendicular magnetization pattern PMP, a perpendicularity enhancing pattern PEP.

The perpendicularity enhancing pattern PEP may include a non-magnetic metal compound. For example, the perpendicularity enhancing pattern PEP may include a non-magnetic metal oxide. In example embodiments, the perpendicularity enhancing pattern PEP may be formed in such a way that a content ratio of the non-magnetic metal in the non-magnetic metal oxide is greater than that of the stoichiometric ratio. For example, the perpendicularity enhancing pattern PEP may include a non-magnetic metal-rich metal oxide. This makes it possible to reduce resistivity of the perpendicularity enhancing pattern PEP, and thus, it is possible to minimize a reduction in magnetoresistance ratio, which may be caused by the perpendicularity enhancing pattern PEP.

In example embodiments, a concentration of the non-magnetic metal may be substantially uniform over the whole region of the perpendicularity enhancing pattern PEP. This makes it possible to reduce uniformly the resistivity of the perpendicularity enhancing pattern PEP. In example embodiments, the perpendicularity enhancing pattern PEP may include at least one of hafnium-rich hafnium oxide, tantalum-rich tantalum oxide, zirconium-rich zirconium oxide, chromium-rich chromium oxide, vanadium-rich vanadium oxide, molybdenum-rich molybdenum oxide, titanium-rich titanium oxide, tungsten-rich tungsten oxide, yttrium-rich yttrium oxide, magnesium-rich magnesium oxide, or zinc-rich zinc oxide.

In example embodiments, the non-magnetic metal compound of the perpendicularity enhancing pattern PEP may include a non-magnetic metal nitride. For example, perpendicularity enhancing pattern PEP may include at least one of hafnium nitride, tantalum nitride, zirconium nitride, chromium nitride, vanadium nitride, molybdenum nitride, titanium nitride, tungsten nitride, yttrium nitride, magnesium nitride, or zinc nitride. In example embodiments, a content ratio of the non-magnetic metal in the non-magnetic metal nitride may be greater than that of the stoichiometric ratio.

Referring to FIG. 10, the lower magnetic patterns FP may be formed using a damascene process.

For example, the formation of the lower magnetic patterns FP may include forming the insulating gap-filling layer 140 having openings, which may expose top surfaces of the second contact plugs 125 (or the lower electrodes 135), depositing layers MGL and PMI to cover conformally the openings, and then, planarizing the resulting structure. The openings of the insulating gap-filling layer 140 may be formed by anisotropically etching portions of the insulating gap-filling layer 140, and in example embodiments, the openings may be formed in such a way that its upper width is greater than its lower width. Because the lower magnetic patterns FP are locally provided in the openings, upper widths thereof may be greater than lower widths thereof, respectively.

Furthermore, the layers MGL and PMI may be deposited in such a way that a thickness thereof is smaller on a side surface of the opening than on a bottom surface of the opening. This difference in thickness of the layers MGL and PMI may increase a ratio in effective area of the lower magnetic pattern to the opening. As the result of the deposition process, at least one of the layers MGL and PMI may be formed to have ‘U’-shaped vertical section. For example, as shown, in the case where each of the lower magnetic patterns FP includes four layers, three layers may be formed to have ‘U’-shaped vertical sections, except for the uppermost layer.

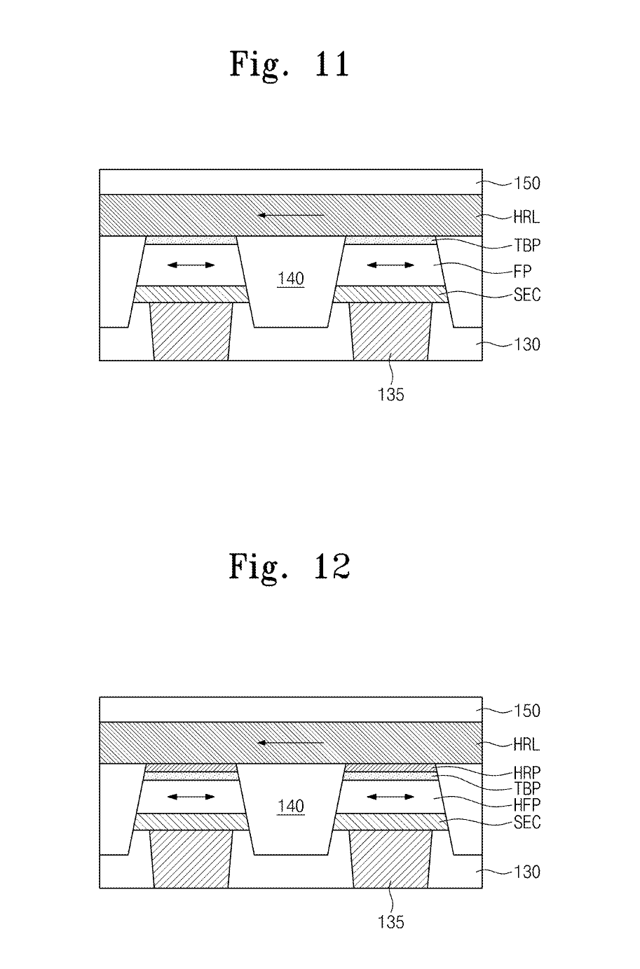

Referring to FIG. 11, the magnetic memory device may include localized tunnel barrier patterns TBP, similar to the lower magnetic patterns FP. For example, the upper magnetic layer HRL may be in direct contact with top surfaces of the tunnel barrier patterns TBP and the insulating gap-filling layer 140.

Referring to FIGS. 12 and 14, the protection metal pattern HRP and PRP may be formed to cover the top surface of the tunnel barrier pattern TBP. The protection metal pattern HRP and PRP may have a top surface that is coplanar with the top surface of the insulating gap-filling layer 140. In addition, the upper magnetic layers HRL and PRL may be in direct contact with top surfaces of the protection metal patterns HRP and PRP and the insulating gap-filling layer 140.

Referring to FIG. 14, the upper magnetic layer PRL may include a perpendicular magnetic structure, which may include alternatingly stacked magnetic and non-magnetic layers MGL and PMI, and a capping electrode layer CEL. The upper magnetic layer PRL may be configured to have a fixed perpendicular magnetization direction. For example, the upper magnetic layer PRL may include at least one of (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n, where the subscript n denotes the stacking number.

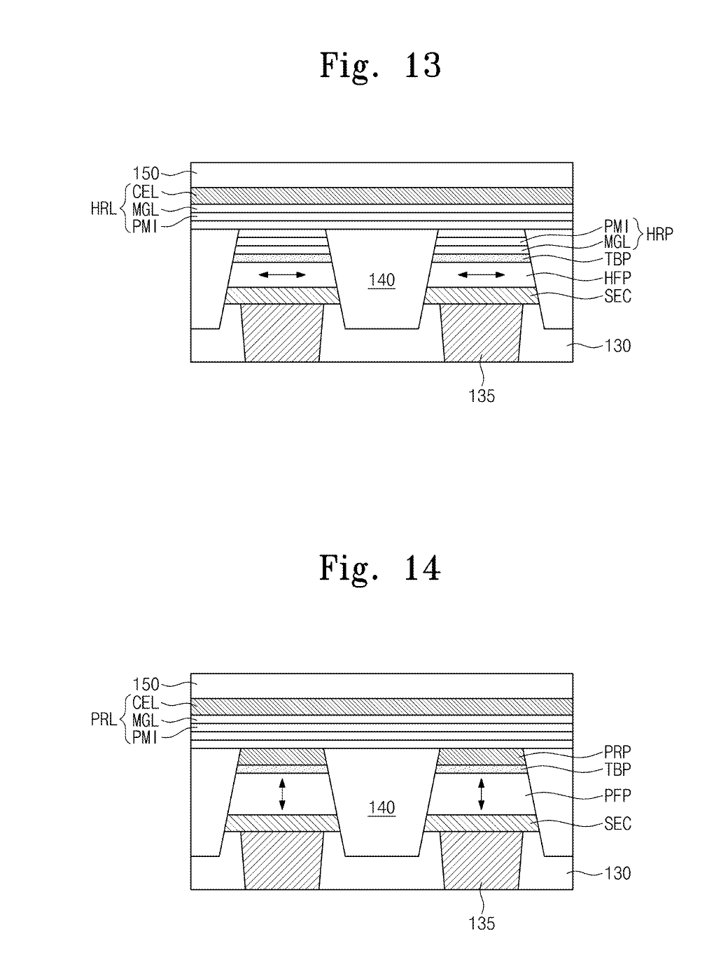

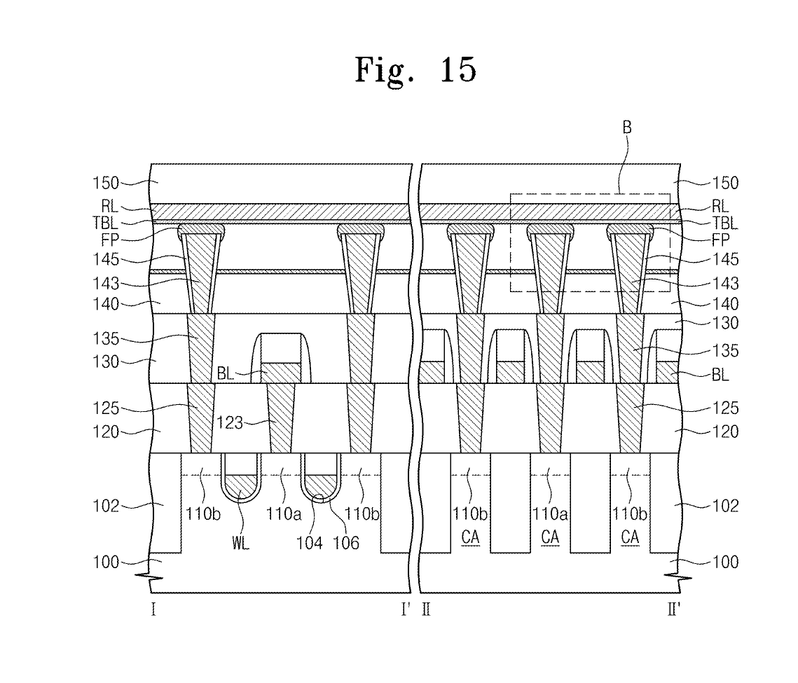

Referring to FIG. 13, the protection metal pattern HRP may include at least one magnetic layer MGL and at least one non-magnetic layer PMI, which may be alternatingly stacked on the substrate.

Referring to FIG. 14, the protection metal pattern PRP may be used for the perpendicularity enhancing pattern PMP described above. For example, the protection metal pattern PRP may include a non-magnetic metal compound. In example embodiments, the protection metal pattern PRP may include a non-magnetic metal oxide. The protection metal pattern PRP may be formed in such a way that a content ratio of non-magnetic metal in the non-magnetic metal oxide is greater than that of the stoichiometric ratio. For example, the protection metal pattern PRP may include a non-magnetic metal-rich metal oxide. This makes it possible to reduce resistivity of the protection metal pattern PRP, and thus, it is possible to minimize a reduction in magnetoresistance ratio, which may be caused by the protection metal pattern PRP.

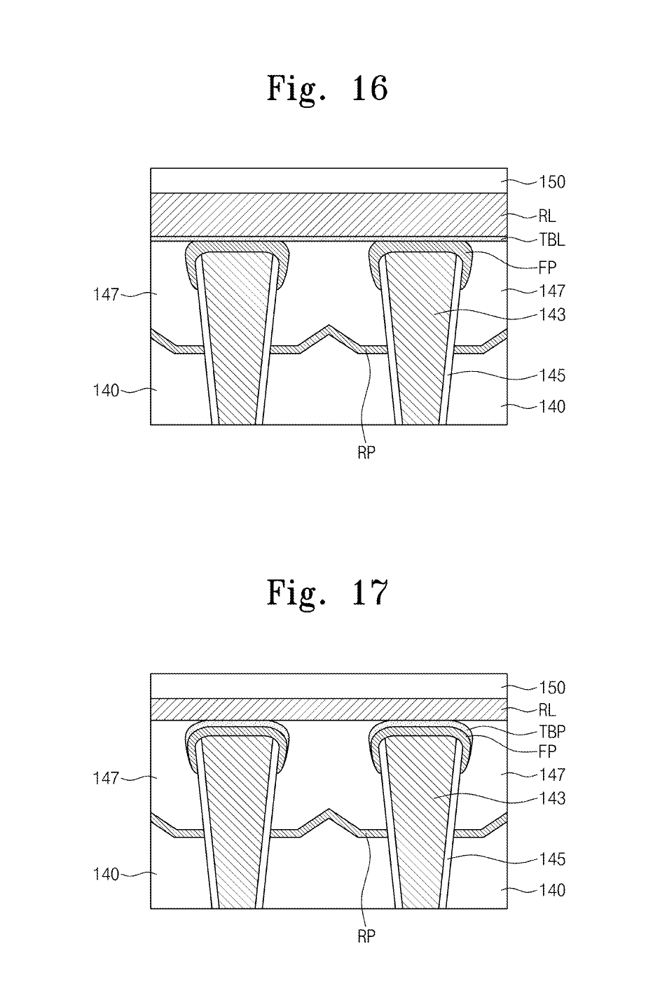

FIG. 15 is a sectional view that is taken along lines I-I′ and II-II′ of FIG. 3 to illustrate magnetic memory devices according to other example embodiments of the inventive concepts. FIGS. 16 through 18 are enlarged sectional views of a portion B of FIG. 15, which are presented to describe memory elements of magnetic memory devices according to other example embodiments of the inventive concepts. For the sake of brevity, the elements and features of this example that are similar to those previously shown and described will not be described in much further detail.

Referring to FIG. 15, the lower magnetic patterns FP may be locally formed to be separated from each other, by not using any patterning process.

For example, the insulating mold pattern 140 may be provided on the second interlayered insulating layer 130. Lower electrodes 143 may be provided in openings, which may be formed through the insulating mold pattern 140 to expose the contact plugs 135, respectively. The lower electrodes 143 may protrude from a top surface of the insulating mold pattern 140. In example embodiments, a ratio of the maximum width (e.g., an upper width) of the lower electrode 143 to a height difference between top surfaces of the lower electrode 143 and the insulating mold pattern 140 may range from about 1:2 to about 1:5.

Furthermore, a width of the lower electrode 143 may increase with increasing distance from the top surface of the insulating mold pattern 140. In other words, an upper width of the lower electrode 143 may be greater than a lower width thereof. Accordingly, the lower electrodes 143 may have a sidewall at an angle with respect to the top surface of the semiconductor substrate 100. The sidewall of the lower electrode 143 and the top surface of the insulating mold pattern 140 may form an acute angle. For example, the sidewall of the lower electrode 143 may form an angle of about 45 to 90 degrees, (preferably, of about 60 to 80 degrees) with respect to the top surface of the insulating mold pattern 140.

In addition, an insulating spacer 145 may be provided on the sidewalls of the lower electrodes 143. The insulating spacers 145 may be formed of an insulating material having an etch selectivity with respect to the insulating mold pattern 140.

According to the present example embodiment, lower magnetic patterns FP may be formed on the lower electrodes 143, respectively. In example embodiments, as shown in FIG. 16, the lower magnetic patterns FP may be formed using a deposition technique having a poor step coverage property (e.g., a physical vapor deposition). As a result, the lower magnetic patterns FP may be discontinuously deposited on the protruding portions of the lower electrodes 143 and on the insulating mold pattern 140. As the result of the discontinuous deposition, each of the lower magnetic patterns FP may be locally formed on the corresponding one of the lower electrodes 143, and the lower magnetic patterns FP may be separated from each other, without an additional patterning process.

In detail, if a layer is deposited by a deposition process having a poor step coverage property, it may be thicker on an upper sidewall of the lower electrode 143 than on a lower sidewall of the lower electrode 143. Further, according to example embodiments of the inventive concepts, because the lower electrodes 143 have a decreasing width toward the bottom, a deposition rate of the lower magnetic patterns FP may be decreased at the sidewall of the lower electrodes 143. In example embodiments, the lower magnetic patterns FP may be formed by using the physical vapor deposition. In this case, the lower magnetic patterns FP may be locally deposited on the top surfaces of the lower electrodes 143 and be separated from each other. Each of the lower magnetic patterns FP may have a rounded edge or a rounded overhang portion. In addition, because the lower magnetic patterns FP have the overhang portions on the sidewall thereof, each of them may have a decreasing width toward the bottom thereof.

As shown in FIG. 16, each of the lower magnetic patterns FP may include a body portion covering the top surface of the lower electrode 143 and an edge portion covering the parts of side surfaces of the lower electrode 143. The body portion of the lower magnetic pattern FP may be formed to have a thickness that is smaller than half the minimum space between the lower electrodes 143. The edge portion of the lower magnetic pattern FP may have a decreasing thickness toward the bottom of the lower electrode 143. As the result of the PVD process, the lower magnetic pattern FP may have a round profile near an upper corner of the lower electrode 143.

In example embodiments, the remaining magnetic patterns RP may be formed on the top surface of the insulating mold pattern 145. Here, during the deposition process with poor step coverage property, the lower magnetic pattern FP may not deposited on the inclined sidewalls of the lower electrodes 143, and thus, the remaining magnetic patterns RP may be electrically separated from the lower magnetic pattern FP.

Referring to FIG. 16, an insulating gap-filling layer 147 may be provided between the lower electrodes 143 and the lower magnetic patterns FP. The insulating gap-filling layer 147 may be in direct contact with the lower magnetic patterns FP. Furthermore, the insulating gap-filling layer 147 may have a top surface that is substantially coplanar with those of the lower magnetic patterns FP. The insulating gap-filling layer 147 may be formed to be in direct contact with the insulating spacer 145 covering the sidewall of the lower electrode 143.

As described with reference to FIGS. 5 through 10, the tunnel barrier layer TBL and the upper magnetic layer RL may be formed to cover the resulting structure provided with the lower magnetic patterns FP and each of them may be shaped like a plate. In example embodiments, top surfaces of the lower magnetic patterns FP and the insulating gap-filling layer 147 may be in direct contact with the tunnel barrier layer TBL.

As shown in FIG. 17, the tunnel barrier patterns TBP may be formed on the lower magnetic patterns FP, respectively.

In example embodiments, the tunnel barrier patterns TBP may be formed using a PVD process, similar to the lower magnetic patterns FP. The insulating gap-filling layer 147 may be in direct contact with a portion of the tunnel barrier pattern TBP and a portion of the lower magnetic pattern FP. In addition, the tunnel barrier layer TBL may be formed to have a top surface that is coplanar with that of the insulating gap-filling layer 147. The upper magnetic layer RL may be in direct contact with the top surfaces of the tunnel barrier patterns TBP and the insulating gap-filling layer 147.

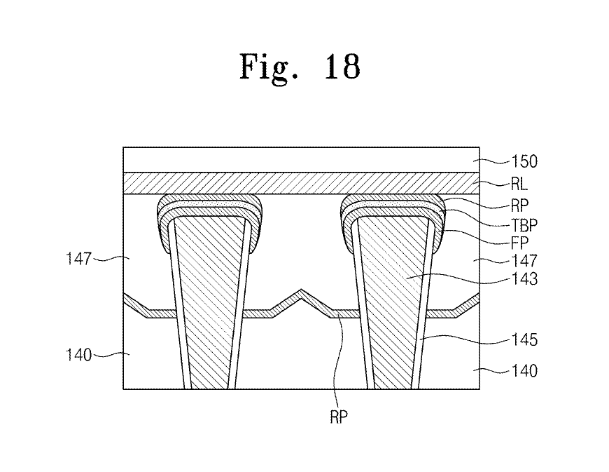

According to the embodiment shown in FIG. 18, the lower magnetic patterns FP, the tunnel barrier patterns TBP, and protection metal patterns RP may be formed on the lower electrodes 143, respectively. In example embodiments, the lower magnetic pattern FP, the tunnel barrier pattern TBP, and the protection metal pattern RP may be sequentially formed using PVD processes.

The protection metal pattern RP, each of the tunnel barrier pattern TBP, and the lower magnetic pattern FP may be partially formed to be in direct contact with the sidewall of the insulating gap-filling layer 147. The upper magnetic layer RL may be in direct contact with the top surfaces of the protection metal pattern RP and the insulating gap-filling layer 147.

In the example embodiments shown in FIGS. 16 through 18, as described above, the lower magnetic patterns FP may serve as a free layer, whose magnetization direction can be changed, while the upper magnetic layer RL may serve as the reference layer, whose magnetization direction is fixed. In addition, the lower magnetic patterns FP and the upper magnetic layer RL may be configured to have magnetization directions that are substantially perpendicular to or parallel to the top surface of the substrate. In example embodiments, the lower magnetic patterns FP may have a thickness that is smaller than that of the upper magnetic layer RL.

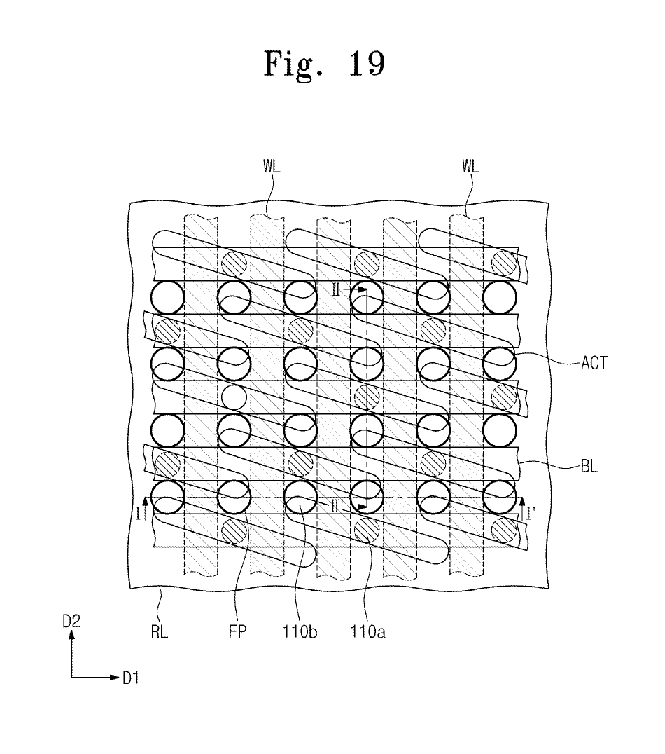

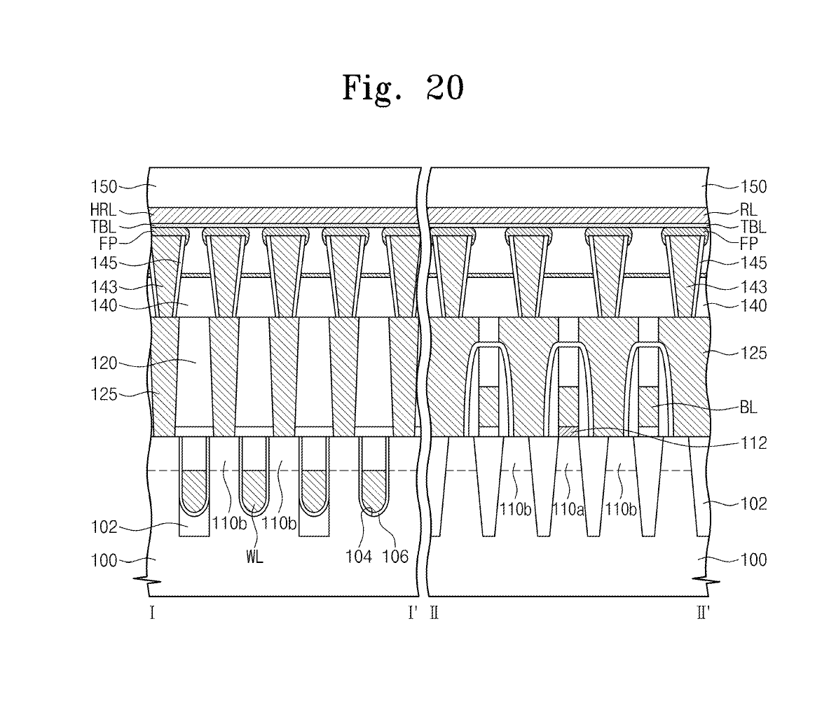

FIG. 19 is a plan view of a magnetic memory device according to other example embodiments of the inventive concepts. FIG. 20 is a sectional view that is taken along lines I-I′ and II-II′ of FIG. 19 to illustrate magnetic memory devices according to other example embodiments of the inventive concepts.

Referring to FIGS. 19 and 20, the active patterns may be formed to have a zigzag arrangement, in plan view, and this make it possible to increase an integration density of the magnetic memory device.

A device isolation layer 101 may be formed on the semiconductor substrate 10 to define the active patterns ACT. In example embodiments, each of the active patterns ACT may be formed to have a bar shape, whose longitudinal axis is parallel to an oblique direction (i.e., to cross the word lines WL and the bit lines BL).

The word lines WL may be provided to cross the active patterns ACT. In example embodiments, the word lines WL may be formed in recess regions, respectively, which are vertically recessed from the top surface of the semiconductor substrate 10, with a gate insulating layer 110 interposed between therebetween. Top surfaces of the word lines WL may be lower than that of the semiconductor substrate 10, and an insulating material may be formed on the word lines WL to fill the remaining spaces of the recess regions.

The first and second impurity regions 110a and 110b may be formed in the active pattern ACT at both sides of each word line WL. The word lines WL and the first and second impurity regions 110a and 110b may constitute a plurality of metal-oxide-semiconductor (MOS) transistors.

The bit lines BL may be provided on the semiconductor substrate 10 to cross the word lines WL. An insulating layer may be interposed between the bit lines BL and the semiconductor substrate 10, and first contact plugs 112 may be formed through the insulating layer to connect the bit lines BL to the first impurity regions 110a, respectively. The first interlayered insulating layer 120 may be formed to cover the bit lines BL, and the second contact plugs 125 may be formed through the first interlayered insulating layer 120 to connect the lower magnetic patterns FP to the second impurity regions 110b, respectively. In example embodiments, the second contact plugs 125 may be provided on portions of the active region ACT, which are positioned at both sides of the bit line BL.

The formation of the second contact plugs 125 may include etching the first interlayered insulating layer 120 to form contact holes exposing the second impurity regions 110b, forming a conductive layer to fill the contact holes, and then planarizing the conductive layer. The second contact plugs 125 may be self-aligned with respect to the bit lines BL. The second contact plug 125 may be formed of a doped polysilicon layer, a metal layer, a metal nitride layer, a metal silicide layer, or any combination thereof.

The lower electrodes 143 may be formed on the second contact plugs 125, respectively. In the present example embodiment, the lower electrode 143 may be formed to have substantially the same technical features as those of the previous example embodiments described with reference to FIGS. 4 and 15. Similarly, the lower magnetic pattern FP, the tunnel barrier layer TBL, and the upper magnetic layer RL may be formed to have substantially the same technical features as those of the previous example embodiments described with FIGS. 4 and 15.

The magnetic memory devices disclosed above may be encapsulated using various and diverse packaging techniques. For example, the magnetic memory devices according to the aforementioned embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a system in package (SIP) technique, a multi-chip package (MCP) technique, a wafer-level fabricated package (WFP) technique and a wafer-level processed stack package (WSP) technique.

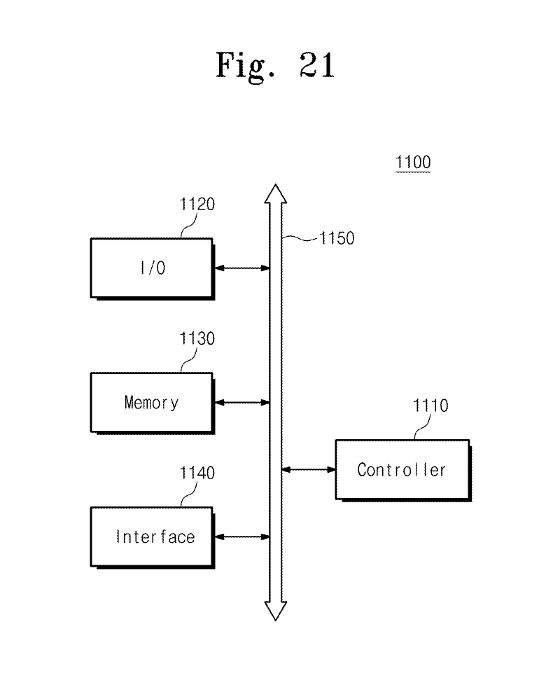

FIG. 21 is a schematic block diagram illustrating an example of electronic systems including a magnetic memory device according to example embodiments of the inventive concepts.

Referring to FIG. 21, an electronic system 1100 according to example embodiments of the inventive concepts may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted. The controller 1110, the input-output unit 1120, the memory device 1130, and/or the interface 1140 may be configured to include one of semiconductor devices according to example embodiments of the inventive concepts.

The controller 1110 may include at least one of a microprocessor, a digital signal processor, a microcontroller or another logic device. The other logic device may have a similar function to any one of the microprocessor, the digital signal processor and the microcontroller. The I/O unit 1120 may include a keypad, a keyboard or a display unit. The memory device 1130 may store data and/or commands. The interface unit 1140 may transmit electrical data to a communication network or may receive electrical data from a communication network. The interface unit 1140 may operate by wireless or cable. For example, the interface unit 1140 may include an antenna for wireless communication or a transceiver for cable communication. The electronic system 1100 may further include a fast DRAM device and/or a fast SRAM device that acts as a cache memory for improving an operation of the controller 1110.

The electronic system 1100 may be applied to a personal digital assistant (PDA), a portable computer, a web tablet, a wireless phone, a mobile phone, a digital music player, a memory card or an electronic product. The electronic product may receive or transmit information data wirelessly.

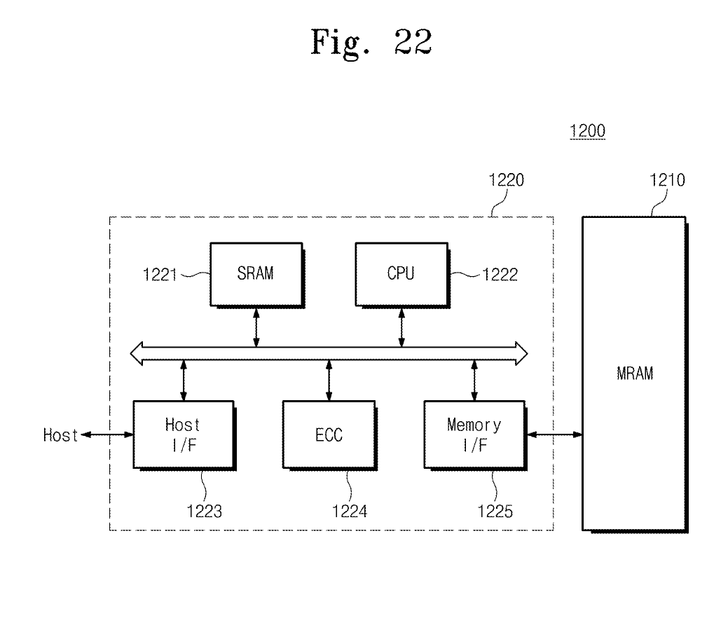

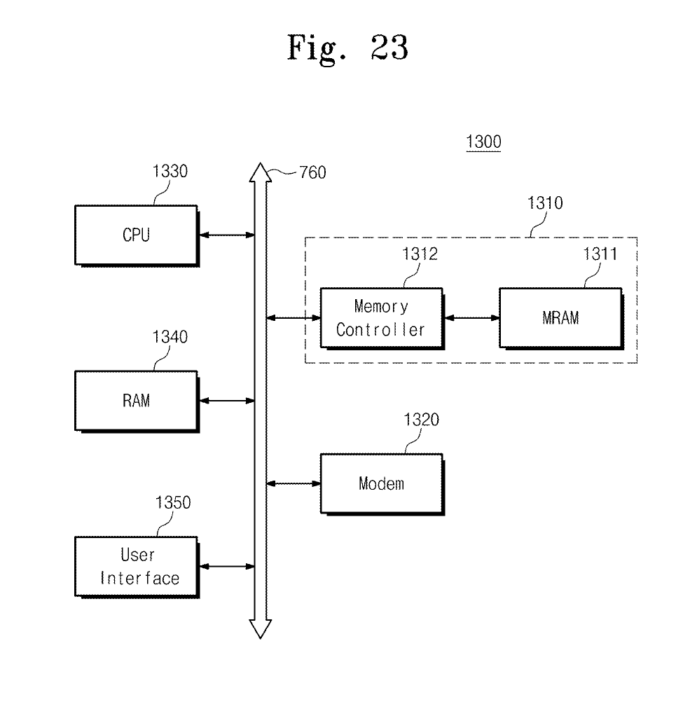

FIG. 22 is a schematic block diagram illustrating an example of memory cards including the magnetic memory devices according to the embodiments of the inventive concepts.

Referring to FIG. 22, a memory card 1200 according to example embodiments of the inventive concepts may include a memory device 1210. The memory device 1210 may include at least one of the semiconductor memory devices according to the afore-described embodiments of the inventive concepts. In other embodiments, the memory device 1210 may further include a semiconductor memory device, which is of a different type from the semiconductor memory devices according to the afore-described embodiments of the inventive concepts. For example, the memory device 1210 may further include a nonvolatile memory device and/or a static random access memory (SRAM) device. The memory card 1200 may include a memory controller 1220 that controls data communication between a host and the memory device 1210. The memory device 1210 and/or the memory controller 1220 may be configured to include at least one of the semiconductor devices according to example embodiments of the inventive concepts.

The memory controller 1220 may include a central processing unit (CPU) 1222 that controls overall operations of the memory card 1200. In addition, the memory controller 1220 may include an SRAM device 1221 used as an operation memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data, which are read out from the memory device 1210. The memory card 1200 may further include a read only memory (ROM) device that stores code data to interface with the host. The memory card 1200 may be used as a portable data storage card. Alternatively, the memory card 1200 may be provided in the form of solid state disks (SSD), instead of hard disks of computer systems.

FIG. 23 is a schematic block diagram illustrating an example of information processing systems including a magnetic memory device according to example embodiments of the inventive concepts.

Referring to FIG. 23, an information processing system 1300 includes a memory system 1310, which may include at least one of the magnetic memory devices according to example embodiments of the inventive concepts. The information processing system 1300 also includes a modem 1320, a central processing unit (CPU) 1330, a RAM 1340, and a user interface 1350, which may be electrically connected to the memory system 1310 via a system bus 1360. The memory system 1310 may include a memory device 1311 and a memory controller 1312 controlling an overall operation of the memory device 1311. Data processed by the CPU 1330 and/or input from the outside may be stored in the memory system 1310. Here, the memory system 1310 may constitute a solid state drive SSD, and thus, the information processing system 1300 may be able to store reliably a large amount of data in the memory system 1310. This increase in reliability enables the memory system 1310 to conserve resources for error correction and realize a high speed data exchange function. Although not shown in the drawing, it will be apparent to those of ordinary skill in the art that the information processing system 1300 may be also configured to include an application chipset, a camera image processor (CIS), and/or an input/output device.

According to example embodiments of the inventive concepts, before etching the tunnel barrier layer, the lower magnetic patterns may be locally formed on the substrate. Accordingly, the lower magnetic pattern, especially metallic materials therein, may not be exposed by an etchant for etching the tunnel barrier layer, and thus, it is possible to suppress the metallic materials from being re-deposited on the sidewalls of the tunnel barrier. This makes it possible to prevent technical problems, such as a formation of electric short circuit between the upper and lower magnetic patterns or deterioration in uniformity characteristics of the magnetic tunnel junction.

Furthermore, the upper magnetic layer having a uniform thickness may be formed to cover all of the lower magnetic patterns, and thus, it is possible to produce a uniform magnetic field between the upper magnetic layer and the lower magnetic patterns. This makes it possible to improve operational characteristics of the magnetic tunnel junction. In addition, the uppermost layer of the magnetic layers may have a plate-shaped structure, and thus, the upper magnetic layer can serve as a magnetic shielding layer.

While example embodiments of the inventive concepts have been particularly shown and described, it will be understood by one of ordinary skill in the art that variations in form and detail may be made therein without departing from the spirit and scope of the attached claims.

1. A magnetic memory device, comprising:
a plurality of lower magnetic patterns arranged on a substrate along first and second directions, the first direction and second direction being orthogonal to each other;
an upper magnetic layer covering at least two of the plurality of lower magnetic patterns arranged along the first direction and at least two of the plurality of lower magnetic patterns arranged along the second direction; and
a tunnel barrier layer between the plurality of lower magnetic patterns and the upper magnetic layer.

2. The device of claim 1, wherein the upper magnetic layer has a magnetization direction fixed perpendicular or parallel to a top surface of the substrate, and
the plurality of lower magnetic patterns each have a magnetization direction changeable to be parallel or anti-parallel to the magnetization direction of the upper magnetic layer.

3. The device of claim 1, wherein the plurality of lower magnetic patterns are electrically separated from each other by an insulating gap-filling layer filling spaces between the plurality of lower magnetic patterns.

4. The device of claim 3, wherein the tunnel barrier layer extends from top surfaces of the plurality of lower magnetic patterns to a top surface of the insulating gap-filling layer.

5. The device of claim 3, wherein the tunnel barrier layer covers top surfaces of the plurality of lower magnetic patterns and is coplanar with a top surface of the insulating gap-filling layer.

6. The device of claim 5, further comprising:
a protection metal pattern between the tunnel barrier layer and the upper magnetic layer,
wherein the upper magnetic layer is in direct contact with a top surface of the protection metal pattern and the top surface of the insulating gap-filling layer.

7. The device of claim 1, wherein an upper width of each of the plurality of lower magnetic patterns is smaller than a lower width thereof.

8. The device of claim 1, further comprising:
an interlayered insulating layer between the substrate and the plurality of lower magnetic patterns;
a plurality of lower electrodes protruding from a top surface of the interlayered insulating layer and each respectively connected to one of plurality of the lower magnetic patterns; and
an insulating spacer surrounding sidewalls of the plurality of lower electrodes,
wherein each of the plurality of lower magnetic patterns comprises a body portion covering a top surface of the lower electrode and an edge portion extending from the body portion to cover a portion of a sidewall of the insulating spacer.

9. The device of claim 1, wherein each of the plurality of lower magnetic patterns comprises a plurality of magnetic layers, and
at least one of the plurality of magnetic layers has a ‘U’-shaped vertical cross-section.

10. A magnetic memory device, comprising:
a semiconductor substrate with an active pattern;
a plurality of word lines extending across the active pattern;
a plurality of first impurity regions and a plurality of second impurity regions formed in the active pattern and located at opposing sides of one of the plurality of word lines;
a plurality of bit lines connected to the first impurity regions and extending across the plurality of word lines;
a plurality of lower magnetic patterns each respectively connected to the second impurity regions;
an upper magnetic layer covering the plurality of lower magnetic patterns; and
a tunnel barrier layer between the plurality of lower magnetic patterns and the upper magnetic layer,
wherein the plurality of word lines and the plurality of bit lines are positioned between the semiconductor substrate and the upper magnetic layer, in vertical cross-sectional view.

11. The device of claim 10, wherein the upper magnetic layer has a magnetization direction fixed to be perpendicular or parallel to a top surface of the substrate, and
the plurality of lower magnetic patterns each have a magnetization direction changeable to be parallel or anti-parallel to the magnetization direction of the upper magnetic layer.

12. The device of claim 10, wherein the plurality of lower magnetic patterns are electrically separated from each other by an insulating gap-filling layer filling spaces between the plurality of lower magnetic patterns.

13. The device of claim 12, wherein the tunnel barrier layer extends from top surfaces of the plurality of lower magnetic patterns to a top surface of the insulating gap-filling layer.

14. The device of claim 13, wherein the tunnel barrier layer covers top surfaces of the plurality of lower magnetic patterns and is coplanar with a top surface of the insulating gap-filling layer.

15. The device of claim 14, further comprising:
a protection metal pattern between the tunnel barrier layer and the upper magnetic layer,
wherein the upper magnetic layer is in direct contact with a top surface of the protection metal pattern and the top surface of the insulating gap-filling layer.

16. The device of claim 10, wherein the plurality of active patterns are parallel to an oblique direction with respect to the plurality of word lines and the plurality of bit lines.

17.-22. (canceled)

23. A magnetic memory device, comprising:
a plurality of word lines extending, in a first direction, within an active region of substrate, wherein a first impurity region and a second impurity region are respectively formed within the active region of the substrate and on opposing sides of each of the word lines;
a plurality of bit lines extending a second direction, wherein the second direction is substantially perpendicular to the first direction, and the plurality of bit lines are electrically connected to and extend over the first impurity region along the second direction;
a magnetic tunnel junction including a free layer pattern, at least one insulating layer and at least one reference layer sequentially stacked,
wherein the free layer pattern extends along the first direction over the entire active region except for regions corresponding to the word lines and the bit lines, and
the free layer pattern extends over the first and second impurity regions along the second direction.

24. The magnetic memory device of claim 23, wherein the free layer pattern extends over the first impurity region along the first direction.

25. The memory device of claim 23, wherein the reference layer has a fixed magnetization direction, and
the free layer pattern is configured to control an electrical resistance of the magnetic tunnel junction by changing a magnetization direction of the free layer pattern to either a parallel state or an antiparallel state relative to the magnetization direction of the reference layer.

26. The memory device of claim 23, wherein the free layer pattern consists of a plurality of line patterns each arranged two-dimensionally over the active region of the substrate.

27.-30. (canceled)
